(19) United States
(12) Patent Application Publication
(10) Pub. No.: US 2025/0204087 A1
(43) Pub. Date: Jun. 19, 2025

(54) CHARGE STORAGE STRUCTURE AND METHOD FOR MANUFACTURING CHARGE STORAGE STRUCTURE

(71) Applicant: JIANGSU LEADMICRO NANO TECHNOLOGY CO., LTD., Wuxi, Jiangsu (CN)

(72) Inventor: Baochen LIAO, Wuxi (CN)

(21) Appl. No.: 18/847,948

(22) PCT Filed: Dec. 23, 2022
(86) PCT No.: PCT/CN2022/141445

§ 371 Date: Sep. 17, 2024

(30) Foreign Application Priority Data
Sep. 8, 2022 (CN) 202211097547.9
Sep. 8, 2022 (CN) 202211097786.4

(51) Int. Cl. H10F 77/70; H10F 71/00; H10F 77/20; H10F 77/30

(52) U.S. Cl. CPC H10F 77/703; H10F 71/128; H10F 71/129; H10F 77/219; H10F 77/311

(57) ABSTRACT

Embodiments of the present application relate to a charge storage structure and a method for manufacturing the charge storage structure. The charge storage structure according to an embodiment includes a wafer, a first polar region, and a second polar region. The wafer has a first surface and a second surface opposite to the first surface, wherein the first surface has a first texture, and the second surface includes a first part with a second texture and a second part connected to the first part; the first polar region is configured to be in contact with the first part of the second surface; the second polar region is spaced apart from the first polar region and is configured to be adjacent to the second part of the second surface; and the first texture is different from the second texture. The charge storage structure and the method for manufacturing the charge storage structure provided in the embodiments of the present application have the advantages of lower manufacturing cost and higher manufacturing efficiency, and can flexibly set a texture on a front surface of a battery and a texture in an opening of a back surface of the battery according to specific needs, so as to meet different product requirements.

### CROSS REFERENCE TO RELATED APPLICATIONS

This application is a national stage application of International Application No. PCT/CN2022/141445 filed Dec. 23, 2022, which claims priority to China Patent Application No. 202211097786.4 filed Sep. 8, 2022 and China Patent Application No. 202211097547.9 filed Sep. 8, 2022. The entire disclosures of the above applications are incorporated herein by reference in their entirety.

### BACKGROUND OF THE INVENTION

### 1. Field of the Invention

Embodiments of the present application relate to the field of charge storage structures, and in particular, to a charge storage structure and a method for manufacturing the charge storage structure.

### 2. Description of the Related Art

Solar cells are typically photovoltaic devices that directly convert sunlight into electricity. Currently popular Interdigitated Back Contact (IBC) solar cells in the market are generally made of silicon wafers. However, the existing IBC solar cell manufacturing process involves many steps, requires use of various kinds of equipment, and has high manufacturing costs, which cannot meet the market needs.

Therefore, the industry hopes to obtain IBC solar cells with lower manufacturing costs, higher manufacturing efficiency, and better performance, and hopes to obtain a method for manufacturing a charge storage structure that can improve the manufacturing efficiency and reduce the manufacturing costs.

### SUMMARY OF THE INVENTION

Embodiments of the present application aim to provide a charge storage structure and a method for manufacturing the charge storage structure, which have lower manufacturing costs and higher manufacturing efficiency and can be flexibly designed into various forms according to different needs.

A charge storage structure provided according to an embodiment of the present application includes: a wafer, having a first surface and a second surface opposite to the first surface, where the first surface has a first texture, and the second surface includes a first part with a second texture and a second part connected to the first part; a first polar region, configured to be in contact with the first part of the second surface; and a second polar region, spaced apart from the first polar region and configured to be adjacent to the second part of the second surface, where the first texture is different from the second texture.

In some embodiments of the present application, the first texture is any one of a pyramidal texture and an inverted pyramidal texture, and the second texture is any one of an alkali polished texture, an acid polished texture, a micro-texture, the pyramidal texture, and the inverted pyramidal texture.

In some embodiments of the present application, the charge storage structure further includes an oxide layer covering the second part of the second surface of the wafer.

In some embodiments of the present application, the charge storage structure further includes a semiconductor layer covering the oxide layer.

In some embodiments of the present application, the charge storage structure further includes a first passivation layer, which covers the first surface, the first part of the second surface, a third surface of the wafer located between the first surface and the second surface, a side surface of the oxide layer, and a side surface of the semiconductor layer.

In some embodiments of the present application, the charge storage structure further includes a second passivation layer covering the first passivation layer.

In some embodiments of the present application, the first polar region includes a first metal contact and a region connected to the first metal contact.

In some embodiments of the present application, the region is an N+ polar region or a P+ polar region.

In some embodiments of the present application, both the first passivation layer and the second passivation layer located on the first part of the second surface have a first opening, and the first metal contact of the first polar region passes through the first opening.

In some embodiments of the present application, the second polar region includes a second metal contact connected to the semiconductor layer, and the second metal contact is connected to the semiconductor layer without passing through an opening.

In some embodiments of the present application, the first metal contact is aluminum.

In some embodiments of the present application, the second metal contact is silver paste or silver aluminum paste.

In some embodiments of the present application, the wafer is a P-type C—Si wafer.

In some embodiments of the present application, the semiconductor layer includes a group IV element.

In some embodiments of the present application, the semiconductor layer includes a group V element.

In some embodiments of the present application, the semiconductor layer includes phosphorus.

In some embodiments of the present application, the second part of the second surface is a flat surface.

In some embodiments of the present application, the oxide layer is a tunneling oxide layer.

In some embodiments of the present application, the inverted pyramidal texture has a reflectivity of 2% to 15%.

In some embodiments of the present application, the pyramidal texture has a reflectivity of about 5% to 20%.

In some embodiments of the present application, the micro-texture has a reflectivity of about 12%.

A charge storage structure provided according to an embodiment of the present application includes: a wafer, having a first surface and a second surface opposite to the first surface, where the first surface has a first texture, and the second surface includes a first part with a second texture and a second part connected to the first part; a first polar region, configured to be in contact with the first part of the second surface; and a second polar region, spaced apart from the first polar region and configured to be adjacent to the second part of the second surface; where the first texture is any one of an alkali polished texture, an acid polished texture, a micro-texture, and an inverted pyramidal texture, and the second texture is any one of an alkali polished texture, an acid polished texture, a micro-texture, and an inverted pyramidal texture; and the first texture and the second texture are the same.

In some embodiments of the present application, the inverted pyramidal texture has a reflectivity of about 2% to 15%.

A method for manufacturing a charge storage structure provided according to an embodiment of the present application includes: depositing an oxide layer on a back surface of a wafer; depositing a semiconductor layer on the oxide layer to cover the oxide layer; depositing a mask layer on the semiconductor layer to cover the semiconductor layer; and removing a portion of the mask layer on the back surface of the wafer to form a first opening.

In some embodiments of the present application, a front surface of the wafer opposite to the back surface includes a second opening exposed from the mask layer, the semiconductor layer, and the oxide layer.

In some embodiments of the present application, the method for manufacturing the charge storage structure further includes: performing a surface texturing process on a region where the first opening and the front surface of the wafer are located.

In some embodiments of the present application, the method for manufacturing the charge storage structure further includes: depositing the oxide layer on a side surface of the wafer located between the front surface and the back surface.

In some embodiments of the present application, the method for manufacturing the charge storage structure further includes: removing the mask layer and the semiconductor layer which are located on the front surface and the side surface of the wafer before performing the surface texturing process.

In some embodiments of the present application, the method for manufacturing the charge storage structure further includes: removing the oxide layer located on the front surface and the side surface of the wafer and the mask layer on the back surface of the wafer.

In some embodiments of the present application, the method for manufacturing the charge storage structure further includes: depositing a first passivation layer on the front surface and the back surface; depositing a second passivation layer on the first passivation layer to cover the first passivation layer; and removing a portion of the first passivation layer and a portion of the second passivation layer on the back surface of the wafer from the first opening to form a third opening that exposes the wafer.

In some embodiments of the present application, the method for manufacturing the charge storage structure further includes: forming a first contact in the third opening; and performing a co-firing process to form a first region at a portion that is adjacent to the first contact and is in contact with the wafer.

In some embodiments of the present application, the method for manufacturing the charge storage structure further includes: forming a second contact in a region outside the third opening; and performing the co-firing process to allow the second contact to pass through the second passivation layer and the first passivation layer to be connected to the semiconductor layer.

In some embodiments of the present application, the oxide layer is deposited using a Plasma Enhanced Chemical Vapor Deposition (PECVD) or Plasma Enhanced Atomic Layer Deposition (PEALD).

In some embodiments of the present application, the semiconductor layer is deposited using PECVD or PEALD.

In some embodiments of the present application, the mask layer is deposited using PECVD or PEALD.

In some embodiments of the present application, the semiconductor layer includes a group IV element.

In some embodiments of the present application, the semiconductor layer includes a group V element.

In some embodiments of the present application, the semiconductor layer includes phosphorus.

In some embodiments of the present application, the mask layer is selected from aluminum oxide, silicon oxide, silicon nitride, silicon oxynitride, silicon carbide, or any combination thereof.

In some embodiments of the present application, the method for manufacturing the charge storage structure further includes: performing an annealing process after depositing the mask layer.

In some embodiments of the present application, the first opening is formed using a laser process.

In some embodiments of the present application, a portion of the passivation layer in the first opening is removed using a laser process to form the third opening.

In some embodiments of the present application, the first passivation layer is deposited using ALD or CVD.

In some embodiments of the present application, the second passivation layer is deposited using PECVD, ALD, or CVD.

Compared with the conventional charge storage structure, the charge storage structure provided according to the embodiments of the present application has lower manufacturing costs, higher manufacturing efficiency, and better product quality and yield. Moreover, compared with the conventional method for manufacturing the charge storage structure, the method for manufacturing the charge storage structure provided according to the embodiments of the present application includes a fewer number of manufacturing steps, which reduces a quantity of manufacturing equipment required to be called, reduces the process difficulty, saves some production materials, and improves the product yield. Therefore, this not only effectively improves the manufacturing efficiency, but also reduces the manufacturing cost and improves the product quality.

### BRIEF DESCRIPTION OF THE DRAWINGS

The accompanying drawings required to describe the embodiments of the present application or the prior art to facilitate description of the embodiments of the present application will be briefly explained below. It is obvious that the accompanying drawings in the following description are only some embodiments of the present application. For those skilled in the art, drawings of other embodiments can still be obtained based on the structures illustrated in these accompanying drawings without creative work. Moreover, the accompanying drawings disclosed here are only for illustrative purposes and do not represent correct proportions of the structures of the embodiments of the present application.

FIG. 1 is a schematic longitudinal cross section view of a charge storage structure according to an embodiment of the present application;

FIG. 2 is a schematic longitudinal cross section view of a charge storage structure according to another embodiment of the present application;

FIG. 3 is a schematic longitudinal cross section view of a charge storage structure according to still another embodiment of the present application;

FIG. 4 is a schematic longitudinal cross section view of a charge storage structure according to another embodiment of the present application;

FIG. 5 is a schematic longitudinal cross section view of a charge storage structure according to still another embodiment of the present application;

FIG. 6 is a schematic longitudinal cross section view of a charge storage structure according to another embodiment of the present application;

FIG. 7 is a schematic longitudinal cross section view of a charge storage structure according to still another embodiment of the present application;

FIG. 8 is a schematic longitudinal cross section view of a charge storage structure according to another embodiment of the present application;

FIG. 9 is a schematic longitudinal cross section view of a charge storage structure according to still another embodiment of the present application;

FIG. 10 is a schematic longitudinal cross section view of a charge storage structure according to another embodiment of the present application;

FIG. 11 is a schematic longitudinal cross section view of a charge storage structure according to still another embodiment of the present application;

FIG. 12 is a schematic longitudinal cross section view of a charge storage structure according to the prior art;

FIG. 13 is a schematic longitudinal cross section view of a charge storage structure according to another embodiment of the present application;

FIG. 14 is a flowchart of a method for manufacturing a charge storage structure according to an embodiment of the present application; and

FIG. 15A, FIG. 15B, FIG. 15C, FIG. 15D, FIG. 15E, FIG. 15F, and FIG. 15G are schematic longitudinal cross section views of charge storage structures at different stages of the charge storage structure, as shown in FIG. 13, manufactured by the method as shown in FIG. 14.

### PREFERRED EMBODIMENT OF THE PRESENT INVENTION

Embodiments of the present application will be described in detail below. In the entire specification of the present application, identical or similar components and components with identical or similar functions are represented by similar reference numerals. The embodiments described herein regarding the accompanying drawings are illustrative and graphical, and are intended to provide a basic understanding of the present application. The embodiments of the present application should not be interpreted as limitations to the present application.

As used herein, the terms “about”, “substantially”, and “essentially” are used for describing and explaining minor changes. When used in conjunction with an event or circumstance, the terms may refer to examples where the event or circumstance occurs precisely and examples where the event or circumstance occurs very approximately. For example, when used in conjunction with numerical values, the terms can refer to a range of variation of less than or equal to ±10% of the numerical values, such as less than or equal to ±5%, less than or equal to ±0.5%, or less than or equal to ±0.05%. For example, if a difference between two numerical values is less than or equal to ±10% of an average value of the values, it may be considered that the two numerical values are “substantially” the same.

Further, for ease of description, “first”, “second”, “third”, and the like may be used herein to distinguish different components of a graph or a series of graphs. “First”, “second”, “third”, and the like are not intended to describe the corresponding components.

In the present application, unless otherwise specified or limited, the terms “arrange”, “connect”, “couple”, “fix”, and similar terms are widely used, and those skilled in the art may understand the above terms based on specific circumstances, such as fixed connection, detachable connection, or integrated connection. It can also be mechanical or electrical connection. It can also be direct connection or indirect connection through an intermediate structure. It can also be internal communication between two components.

The present application provides a novel charge storage structure, which has higher quality and lower manufacturing costs.

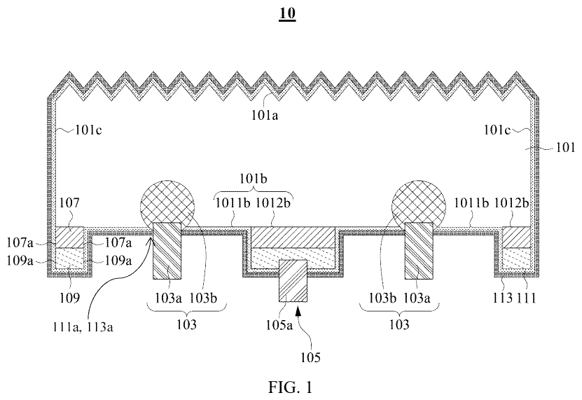

FIG. 1 is a schematic longitudinal cross section view of a charge storage structure 10 according to an embodiment of the present application.

As shown in FIG. 1, the charge storage structure 10 according to an embodiment of the present application may include: a wafer 101, a polar region 103, a polar region 105, an oxide layer 107, a semiconductor layer 109, a passivation layer 111, and a passivation layer 113. The charge storage structure 10 can be, for example, but not limited to, an Interdigitated Back Contact (IBC) solar cell.

The wafer 101 may have a surface 101a, a surface 101b opposite to the surface 101a, and a surface 101c located between the surface 101a and the surface 101b. The wafer 101 may be, for example, but not limited to, a P-type C—Si wafer. The wafer 101 may be any suitable type of wafer. The surface 101a may have a texture. The texture is a surface obtained by performing a texturing process on a surface of a silicon wafer. A good texture structure can reduce the reflectivity of the sunlight, enhance light absorption, and improve the characteristics such as surface passivation and electrode contact, thereby improving the collection efficiency of charge carriers. The texture of the surface 101a may be a pyramidal texture. The pyramidal texture may substantially present an uneven triangular structure. A contact area between the pyramidal texture and metal is large, so that an effective metallization area is enlarged. However, during deposition of a passivation layer on the pyramidal texture, ensuring the film uniformity of the deposition of the passivation layer is a challenge. The pyramidal texture may reflect the sunlight twice. Different processes may form pyramidal textures with different reflectivities. The pyramidal texture may have a reflectivity of, for example, but not limited to, about 5% to 20%, about 5% to 10%, about 6% to 11%, about 10% to 15%, and about 15% to 20%. The texture of the surface 101a may also be any one of a pyramidal texture, an alkali polished texture, an acid polished texture, a micro-texture, or an inverted pyramidal texture. The alkali polished texture may present a substantially flat surface. The substantially flat surface of the alkali polished texture is favorable for the deposition of the passivation layer, but is not favorable for metal contacting. Compared to the pyramidal texture or the inverted pyramidal texture, the substantially flat surface of the alkali polished texture has a smaller contact area with the metal. Furthermore, due to the flat surface, the metal is easy to diffuse, resulting in a large final metal contact area. The reflectivity of the alkali polished texture is greater than about 40%. The acid polished texture may present a surface with a plurality of continuous substantially curved structures. The acid polished texture may have a reflectivity of about 30% to 35%. The micro-texture may be a surface with both an alkali polished shape and a pyramidal shape. The micro-texture combines the advantages of the pyramidal texture and the alkali polished texture, which not only enlarges the effective metallization area, but also ensures the film uniformity of the deposition of the passivation layer. The micro-texture may have a reflectivity of about 10% to 15%. The inverted pyramidal texture may present a substantially inverted pyramidal shape. The inverted pyramidal texture may reflect the sunlight for three times. The inverted pyramidal texture has better light trapping ability and carries higher current compared to the pyramidal texture. A metalized printed inverted pyramid can be designed with a smaller line width and a better height-to-width ratio, and the inverted pyramidal texture is in better contact with the metal, which can improve the efficiency of a solar cell. The inverted pyramidal texture may have a reflectivity of, for example, but not limited to, about 2% to 15%, about 2% to 10%, about 5% to 10%, about 8% to 10%, about 10% to 12%, and about 10% to 15%. The reflectivity of the inverted pyramidal texture with a nano columnar shape may be low. The texture of the surface 101a may be preferably a pyramidal texture or an inverted pyramidal texture to better reduce the reflectivity of the sunlight and absorb the sunlight as much as possible.

The surface 101b may include a first part 1011b and a second part 1012b connected to the first part 1011b. The first part 1011b may have a texture. The texture of the first part 1011b may be alkali polished texture. The texture of the first part 1011b may be different from the texture of the surface 101a. The texture of the first part 1011b may be any one of an acid polished texture, a micro-texture, a pyramidal texture, or an inverted pyramidal texture. The second part 1012b of the surface 101b may be a flat surface. The texture of the first part 1011b may be preferably an alkali polished texture, an acid polished texture, or a micro-texture. The texture of the first part 1011b may be the same as that of the surface 101a. The texture of the surface 101a and the texture of the first part 1011b of the surface 101b may be flexibly set according to a specific need to meet different product requirements.

The polar region 103 may be configured to be in contact with the first part 1011b of the surface 101b. The polar region 103 may include a metal contact 103a and a region 103b connected to the metal contact 103a. The metal contact 103a may be, for example, but not limited to, aluminum. The metal contact 103a may be set using a conventional screen printing process or any suitable process. The metal contact 103a may be a base contact. In other embodiments of the present application, the metal contact 103a may include any suitable material. The region 103b may be an N+ polar region or a P+ polar region. The region 103b may be formed by performing a co-firing process to treat a portion that is adjacent to the metal contact 103a and is in contact with the wafer 101. The region 103b may not include boron.

The polar region 105 may be spaced apart from the polar region 103 and is configured to be adjacent to the second part 1012b of the surface 101b. The polar region 105 may include a metal contact 105a. The metal contact 105a may pass through a passivation layer 113 and a passivation layer 111 to be connected to the semiconductor layer 109. The metal contact 105a may be, for example, but not limited to, silver paste, or silver aluminum paste. The metal contact 105a may be an emitter contact. The metal contact 105a may be set using a conventional screen printing process or any suitable process. In other embodiments of the present application, the metal contact 105a may include any suitable material. The metal contact 105a may be connected to the semiconductor layer 109 without passing through an opening. The silver paste or silver aluminum paste is corrosive and may pass through the passivation layer 113 and the passivation layer 111 to be connected to the wafer 101 during the co-firing. Therefore, it is not necessary to first open the passivation layer 113 and the passivation layer 111 to form an opening to connect the silver paste or silver aluminum paste to the wafer 101. The metal contact 105a and the metal contact 103a may be located on different horizontal planes.

The oxide layer 107 may cover the second part 1012b of the surface 101b of the wafer 101. The oxide layer 107 may be, for example, but not limited to, a SiOx layer with the thickness of less than 5 nanometers. The oxide layer 107 may be any suitable type of oxide layer. The oxide layer 107 may be deposited using Plasma Enhanced Chemical Vapor Deposition (PECVD) or Plasma Enhanced Atomic Layer Deposition (PEALD). The PEALD process may be performed at a temperature ranging from about 100° C. to 500° C. to form the oxide layer 107. The oxide layer 107 may be a tunneling oxide layer.

The semiconductor layer 109 may cover the oxide layer 107. The semiconductor layer 109 may include a group IV element. The semiconductor layer 109 may include a group V element. The semiconductor layer 109 may include, for example, but not limited to, phosphorus. The semiconductor layer 109 may include, for example, but not limited to, in-situ doped phosphorus. The semiconductor layer 109 may include, for example, but not limited to, phosphine (PH₃). The semiconductor layer 109 may be any suitable type of semiconductor layer. The semiconductor layer 109 may be a polysilicon layer. The semiconductor layer 109 may be deposited using the PECVD or the PEALD. The PECVD process may be performed at a temperature ranging from about 100° C. to 500° C. to form the semiconductor layer 109.

The passivation layer 111 may cover the surface 101a, the first part 1011b of the surface 101b, the surface 101c between the surface 101a and the surface 101b of the wafer 101, a side surface 107a of the oxide layer 107, and a side surface 109a of the semiconductor layer 109. In other embodiments of the present application, the passivation layer 111 may cover the surface 101a, the first part 1011b of the surface 101b, a side surface 107a of the oxide layer 107, and a side surface 109a of the semiconductor layer 109. The passivation layer 111 located on the first part 1011b of the surface 101b may have an opening 111a. The metal contact 103a passes through the opening 111a to be connected to the wafer 101 after the co-firing process is performed, so as to form a region 103b. The passivation layer 111 may be, for example, but not limited to, an AlOx layer. The passivation layer 111 may be, for example, but not limited to, Al₂O₃. The passivation layer 111 may be any suitable type of oxide layer. The passivation layer 111 may be a SiOx layer. The passivation layer 111 may be a stacked layer of the SiOx layer and the Al₂O₃ layer, and SiOx may be relatively thin, for example, having a thickness of about 2 nm or less. The passivation layer 111 may be deposited using ALD, CVD, or any suitable process. The passivation layer 111 that is deposited on two sides (namely, on the surface 101a and the surface 101b) may overcome a wrap plating problem caused by single-sided deposition.

The passivation layer 113 may cover the passivation layer 111. The passivation layer 113 located on the first part 1011b of the surface 101b may have an opening 113a. The opening 111a is communicated to the opening 113a. The metal contact 103a of the polar region 103 passes through the opening 111a and the opening 113a. The passivation layer 113 may be, for example, but not limited to, a SiNx layer, a SiOx layer, a SiON layer, or any combined layer of the SiNx layer, the SiOx layer, and the SiON layer. The passivation layer 113 may be any suitable type of nitride layer. The passivation layer 113 may be deposited using ALD, CVD, PECVD, PEALD, or any suitable process to coat the passivation layer 111. The passivation layer 113 may be an anti-reflection layer. The passivation layer 113 may provide further hydrogen passivation for the passivation layer 111.

As shown in FIG. 1 of the present application, the charge storage structure 10 does not include boron, thus the manufacturing cost is low. A high-temperature boron diffusion process is no longer used, and a wet process does not need to be performed to clean products of boron diffusion wrap-around plating. Furthermore, the key layers of the devices, the oxide layer, the semiconductor layer and the mask layer can be deposited continuously in a process tube without breaking the vacuum by using a new tool which combines PEALD and PECVD two deposition techniques into one process tube. This greatly reduces the number of manufacturing equipment required to be used, lowers the difficulty of the process, saves some production materials, reduces the manufacturing cost, and achieves back cross contact in an extremely simple way. Meanwhile, since the boron diffusion process is not used, a maximum temperature that the wafer needs to withstand throughout the manufacturing of the charge storage structure (the temperature of the boron diffusion process is about 1000° C. to 1200° C.) is significantly reduced, thereby reducing the warping problem caused by a high temperature of the wafer 101, improving the product yield of the charge storage structure 10, and reducing the energy consumption. In addition, the oxide layer 107 and the semiconductor layer 109 are manufactured using the PEALD or PECVD process, the thickness of the oxide layer 107 can be well controlled, the uniformity, repeatability, and stability of the oxide layer 107 can be guaranteed, and the deposition rate of the semiconductor layer 109 can be greatly increased. Although depositing the semiconductor layer 109 using the PEALD or PECVD processes cannot completely avoid the wrap plating of the semiconductor layer 109, the wrap plating range of the semiconductor layer 109 can be narrowed to a certain extent due to the limited region of the plasma generation, thereby improving the production efficiency and yield to a certain extent, and reducing the technical bottleneck in a Low Pressure Chemical Vapor Deposition (LPCVD) technology such as frequent tube breakage caused by polysilicon deposition on a quartz tube wall. Therefore, the charge storage structure 10 shown in FIG. 1 of the present application can have higher product quality, lower manufacturing cost, and higher production efficiency.

In addition, the texture on the surface 101a of the wafer and the texture on the surface 101b of the wafer of the charge storage structure 10 shown in FIG. 1 of the present application may be the same or different. This allows those skilled in the art to flexibly design the charge storage structure 10 based on factors such as the product performance and the manufacturing cost to meet different market requirements.

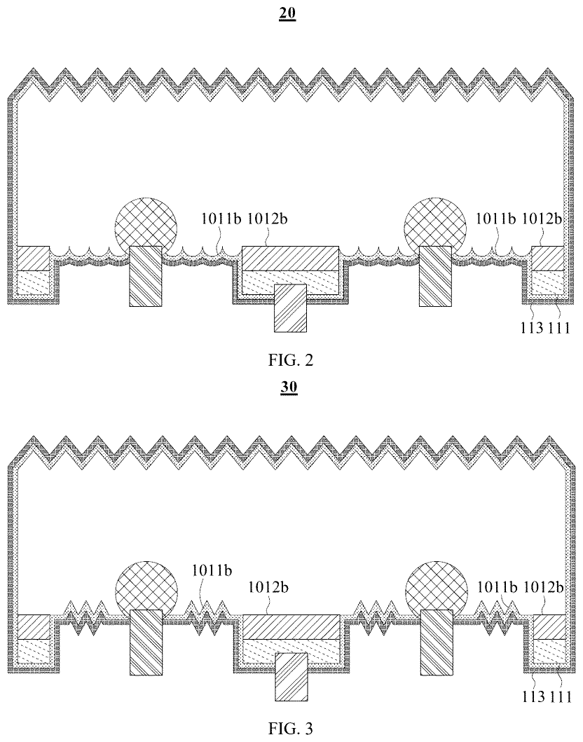

FIG. 2 is a schematic longitudinal cross section view of a charge storage structure 20 according to another embodiment of the present application. As shown in FIG. 2, a difference between the charge storage structure 20 according to an embodiment of the present application and the charge storage structure 10 shown in FIG. 1 is that the texture of the first part 1011b of the surface 101b in the charge storage structure 20 is an acid polished texture.

FIG. 3 is a schematic longitudinal cross section view of a charge storage structure 30 according to another embodiment of the present application. As shown in FIG. 3, a difference between the charge storage structure 30 according to an embodiment of the present application and the charge storage structure 10 shown in FIG. 1 is that the texture of the first part 1011b of the surface 101b in the charge storage structure 30 is a micro-texture, which includes a substantially flat part and a pyramidal part.

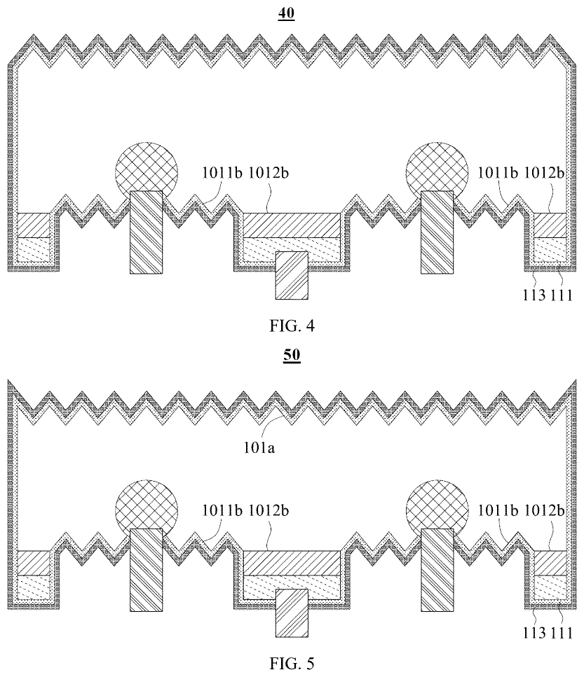

FIG. 4 is a schematic longitudinal cross section view of a charge storage structure 40 according to another embodiment of the present application. As shown in FIG. 4, a difference between the charge storage structure 40 according to an embodiment of the present application and the charge storage structure 10 shown in FIG. 1 is that the texture of the first part 1011b of the surface 101b in the charge storage structure 40 is an inverted pyramidal texture.

FIG. 5 is a schematic longitudinal cross section view of a charge storage structure 50 according to another embodiment of the present application. As shown in FIG. 5, a difference between the charge storage structure 50 according to an embodiment of the present application and the charge storage structure 10 shown in FIG. 1 is that the texture of the surface 101a in the charge storage structure 50 is an inverted pyramidal texture, and the texture of the first part 1011b of the surface 101b is an inverted pyramidal texture.

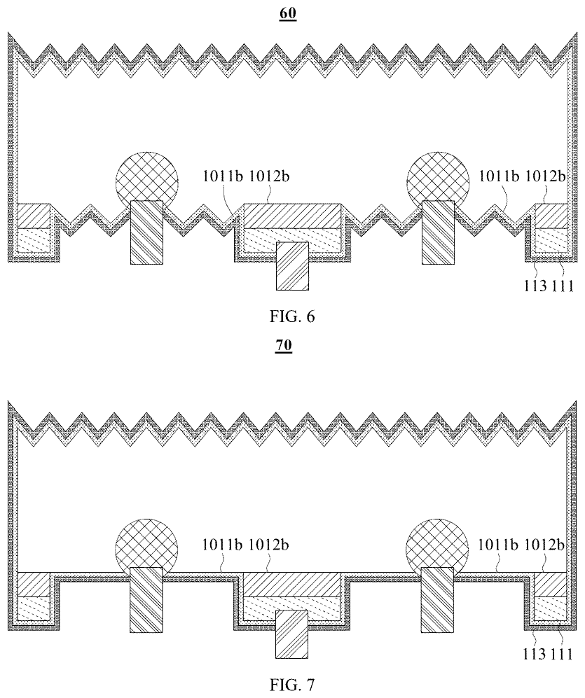

FIG. 6 is a schematic longitudinal cross section view of a charge storage structure 60 according to another embodiment of the present application. As shown in FIG. 6, a difference between the charge storage structure 60 according to an embodiment of the present application and the charge storage structure 50 shown in FIG. 5 is that the texture of the first part 1011b of the surface 101b in the charge storage structure 60 is a pyramidal texture.

FIG. 7 is a schematic longitudinal cross section view of a charge storage structure 70 according to another embodiment of the present application. As shown in FIG. 7, a difference between the charge storage structure 70 according to an embodiment of the present application and the charge storage structure 50 shown in FIG. 5 is that the texture of the first part 1011b of the surface 101b in the charge storage structure 70 is an alkali polished texture.

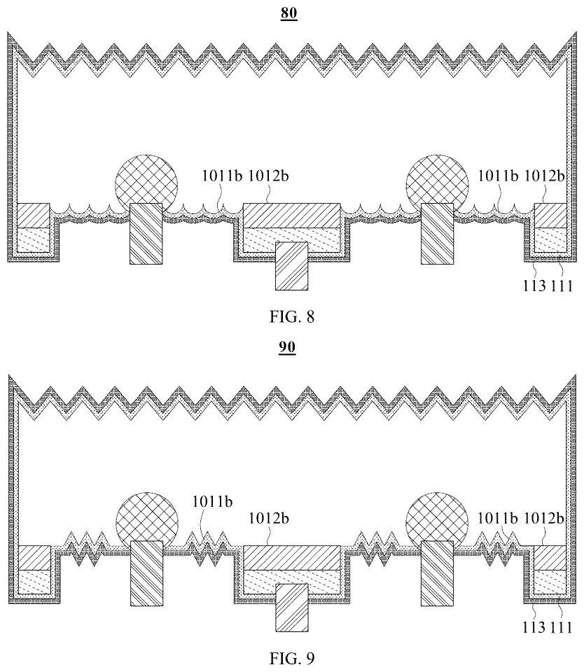

FIG. 8 is a schematic longitudinal cross section view of a charge storage structure 80 according to another embodiment of the present application. As shown in FIG. 8, a difference between the charge storage structure 80 according to an embodiment of the present application and the charge storage structure 50 shown in FIG. 5 is that the texture of the first part 1011b of the surface 101b in the charge storage structure 80 is an acid polished texture.

FIG. 9 is a schematic longitudinal cross section view of a charge storage structure 90 according to another embodiment of the present application. As shown in FIG. 9, a difference between the charge storage structure 90 according to an embodiment of the present application and the charge storage structure 50 shown in FIG. 5 is that the texture of the first part 1011b of the surface 101b in the charge storage structure 90 is a micro-texture, which includes a substantially flat part and a pyramidal part.

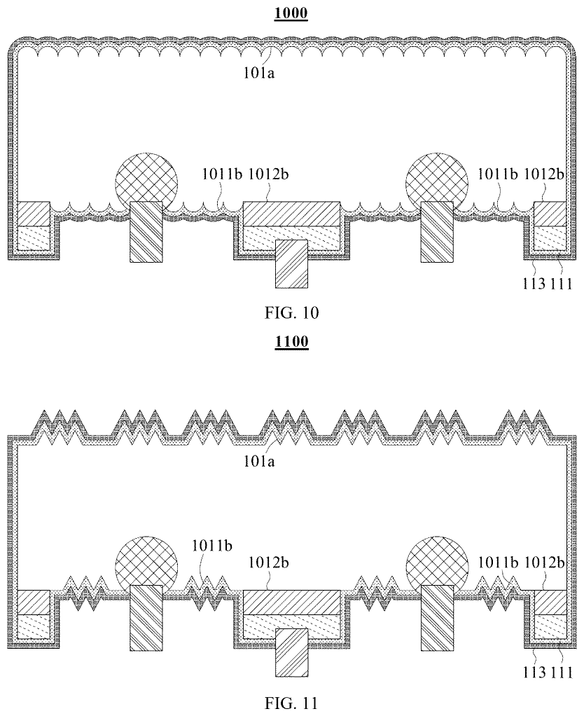

FIG. 10 is a schematic longitudinal cross section view of a charge storage structure 1000 according to another embodiment of the present application. As shown in FIG. 10, a difference between the charge storage structure 1000 according to an embodiment of the present application and the charge storage structure 10 shown in FIG. 1 is that the texture of the surface 101a in the charge storage structure 1000 is an acid polished texture, and the texture of the first part 1011b of the surface 101b is an acid polished texture.

FIG. 11 is a schematic longitudinal cross section view of a charge storage structure 1100 according to another embodiment of the present application. As shown in FIG. 11, a difference between the charge storage structure 1100 according to an embodiment of the present application and the charge storage structure 10 shown in FIG. 1 is that the texture of the surface 101a in the charge storage structure 1100 is a micro-texture, and the texture of the first part 1011b of the surface 101b is a micro-texture.

The texture on the surface 101a of the wafer and the texture on the surface 101b of the wafer of the charge storage structure according to the embodiments of the present application may be flexibly set according to needs to meet different product requirements.

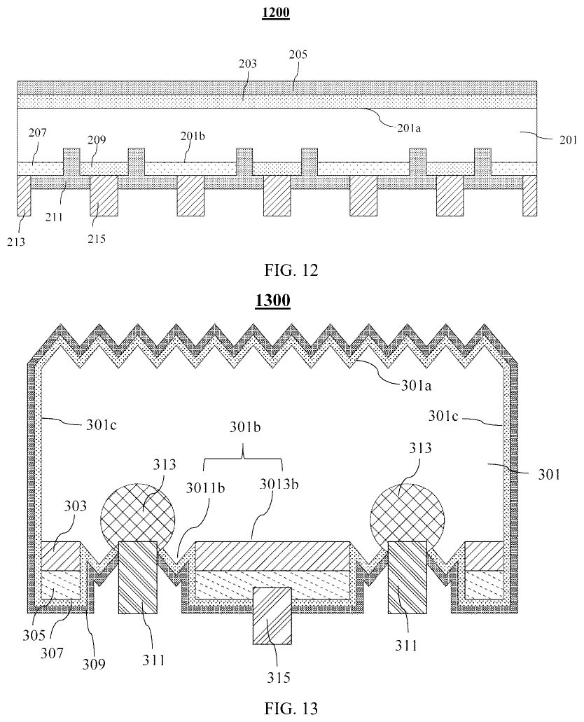

FIG. 12 is a schematic longitudinal cross section view of a charge storage structure according to the prior art.

As shown in FIG. 12, the charge storage structure 1200 according to the prior art may include: a wafer 201, an n-type region 203 arranged on a front surface 201a of the wafer 201, a SiNx layer 205 arranged on the n-type region 203, a P+ region 207 arranged on a back surface 201b of the wafer 201, an N+ region 209 arranged on the back surface 201b of the wafer 201, a surface passivation layer 211 that spaces the P+ region 207 from the N+ region 209, a metal contact 213 connected to the P+ region 207, and a metal contact 215 connected to N+ region 209.

The P+ region 207 may include a p-type dopant source, such as boron. During the formation of the P+ region 207, the p-type dopant source, such as printable boron slurry, needs to be deposited on the back surface 201b of the wafer 201 in a strip-type manner. Then, the wafer 201 is placed in a preheated diffusion furnace at a temperature of about 900° C. to 1400° C. to promote boron diffusion through the back surface 201b so as to perform a process of diffusing the boron into the wafer 201, thus forming the P+ region 207. In another embodiment, the P+ region 207 is formed by depositing a p-type material layer and then performing an ion implantation process. After the ion implantation process is performed, an annealing process is required for repair.

The N+ region 209 may include an n-type dopant, such as phosphorus. The formation of the N+ region 209 is after the formation of the P+ region 207. That is, the temperature of the diffusion furnace ranges from about 850° C. to 900° C., and then the POCl₃ is switched on at a rate of reaching a phosphorus doped profile to achieve a process of diffusing the phosphorus to the wafer 201. In another embodiment, the N+ region 209 is formed by depositing an n-type material layer and then performing an ion implantation process. After the ion implantation process is performed, an annealing process is required for repair.

The charge storage structure 1200 shown in FIG. 12 includes a boron diffusion region 207, equipment that needs to perform the high-temperature boron diffusion process during the manufacturing, and equipment that also needs to perform the wet process, so as to clean the wrap plating formed by the boron diffusion.

The charge storage structure of the present application has fewer manufacturing steps, lower energy consumption, lower cost, higher manufacturing efficiency, and higher quality, can meet a requirement for mass production, and has a wider market prospect. Moreover, the charge storage structure of the present application can achieve different textures on the front and back surfaces of the wafer, taking into account the product requirements and the manufacturing cost. Further, by use of the ALD deposition process to deposit a passivation layer, the present application can ensure the film uniformity and shape retention of the deposition of the passivation layer, so that the charge storage structures of which respective textures can be set have good quality.

The present application provides a novel method for manufacturing a charge storage structure, which may manufacture a charge storage structure more easily and more efficiently at low cost without reducing the quality of the charge storage structure, and even on the premise of further improving the quality of the charge storage structure.

FIG. 13 is a schematic longitudinal cross section view of a charge storage structure 1300 according to another embodiment of the present application.

As shown in FIG. 13, the charge storage structure 1300 according to an embodiment of the present application may include: a wafer 301, an oxide layer 303, a semiconductor layer 305, a passivation layer 307, a passivation layer 309, a contact 311, a first region 313, and a contact 315. The charge storage structure 1300 may include, for example, but not limited to, a IBC solar cell.

The wafer 301 may have a front surface 301a, a back surface 301b opposite to the front surface 301a, and a side surface 301c located between the front surface 301a and the back surface 301b. The wafer 301 may be, for example, but not limited to, a P-type C—Si wafer. The wafer 301 may be any suitable type of wafer. The front surface 301a may include a pyramidal part. The pyramidal shape may substantially present an uneven triangular structure. The front surface 301a may include an alkali polished shape (namely, which may substantially present a flat surface), an acid polished shape (namely, which may substantially present a surface having a plurality of continuous curved structures), a micro-texture shape (namely, which may substantially present a surface that has both an alkali polished shape and a pyramidal shape), or an inverted pyramidal shape. The back surface 301b may be in any shape. The back surface 301b may include a pyramidal part 3011b and a flat part 3013b. In other embodiments of the present application, the pyramidal part 3011b may be any one of the alkali polished shape, an acid polished shape, a micro-texture shape, or an inverted pyramidal shape.

The oxide layer 303 may be arranged on the flat part 3013b of the back surface 301b of the wafer 301. The oxide layer 303 may be, for example, but not limited to, a SiOx layer with the thickness of less than 5 nanometers. The oxide layer 303 may be any suitable type of oxide layer. The oxide layer 303 may be deposited using Plasma Enhanced Chemical Vapor Deposition (PECVD) or Plasma Enhanced Atomic Layer Deposition (PEALD). The PEALD process may be performed at a temperature ranging from about 100° C. to 500° C. to form the oxide layer 303. The oxide layer 303 may be a tunneling oxide layer.

The semiconductor layer 305 may be arranged on the oxide layer 303. The semiconductor layer 305 may include a group IV element. The semiconductor layer 305 may include a group V element. The semiconductor layer 305 may include, for example, but not limited to, phosphorus. The semiconductor layer 305 may include, for example, but not limited to, in-situ doped phosphorus. The semiconductor layer 305 may include, for example, but not limited to, phosphine (PH₃). The semiconductor layer 305 may be any suitable type of semiconductor layer. The semiconductor layer 305 may be a polysilicon layer. The semiconductor layer 305 may be deposited using the PECVD or the PEALD. The PECVD process may be performed at a temperature ranging from about 100° C. to 500° C. to form the semiconductor layer 305.

The passivation layer 307 may wrap the pyramidal part 3011b, the oxide layer 303, and the semiconductor layer 305 on the front surface 301a, the side surface 301c, and the back surface 301b of the wafer 301. The passivation layer 307 may be, for example, but not limited to, an AlOx layer. The passivation layer 307 may be, for example, but not limited to, Al₂O₃. The passivation layer 307 may be any suitable type of oxide layer. The passivation layer 307 may be a SiOx layer. The passivation layer 307 may be a stacked layer of the SiOx layer and the Al₂O₃ layer, and SiOx may be relatively thin, for example, having a thickness of about 2 nm or less. The passivation layer 307 may be deposited using ALD, CVD, or any suitable process. The passivation layer 307 that is deposited on two sides (namely, on the front surface 301a and the back surface 301b) may overcome the wrap plating problem caused by single-sided deposition.

The passivation layer 309 may wrap the passivation layer 307. The passivation layer 309 may be, for example, but not limited to, a SiNx layer, a SiOx layer, a SiON layer, or any combined layer of the SiNx layer, the SiOx layer, and the SiON layer. The passivation layer 309 may be any suitable type of nitride layer. The passivation layer 309 may be deposited using ALD, CVD, PECVD, PEALD, or any suitable process to coat the passivation layer 307. The passivation layer 309 may be an anti-reflection layer. The passivation layer 309 may provide further hydrogen passivation for the passivation layer 307.

The contact 311 is connected to the first region 313. The contact 311 may be, for example, but not limited to, Al. The contact 311 may be set using a conventional screen printing process or any suitable process. The contact 311 may be a base contact. In other embodiments of the present application, the contact 311 may include any suitable material.

The first region 313 may be connected to the contact 311. The first region 313 may be formed by performing a co-firing process to treat a portion that is adjacent to the contact 311 and is in contact with the wafer 301. The first region 313 may be a P+ region. The first region 313 may be an N+ region. The first region 313 does not include boron.

The contact 315 may pass through a passivation layer 309 and a passivation layer 307 to be connected to the semiconductor layer 305. The contact 315 may be, for example, but not limited to, Ag paste, or silver aluminum paste. The contact 315 may be an emitter contact. The contact 315 may be set using a conventional screen printing process or any suitable process. In other embodiments of the present application, the contact 315 may include any suitable material. The contact 315 and the contact 311 may be located on different horizontal planes.

As shown in FIG. 13 of the present application, the charge storage structure 1300 does not include boron, thus a high-temperature boron diffusion process does not need to be used, and a wet process does not need to be performed to clean products of boron diffusion wrap plating. Furthermore, the key layers of the devices, the oxide layer, the semiconductor layer and the mask layer can be deposited continuously in a process tube without breaking the vacuum by using a new tool which combines PEALD and PECVD two deposition techniques into one process tube. This greatly reduces the number of manufacturing equipment required to be used, lowers the difficulty of the process, saves some production materials, reduces the manufacturing cost, and achieves back cross contact in an extremely simple way. Meanwhile, since the boron diffusion process is not used, a maximum temperature that the wafer needs to withstand throughout the manufacturing of the charge storage structure (the temperature of the boron diffusion process is about 1000° C. to 1200° C.) is significantly reduced, thereby reducing the warping problem caused by a high temperature of the wafer 301, improving the product yield of the charge storage structure 1300, and reducing the energy consumption. In addition, the oxide layer 303 and the semiconductor layer 305 are manufactured using the PEALD or PECVD process, the thickness of the oxide layer 303 can be well controlled, the uniformity, repeatability, and stability of the oxide layer 303 can be guaranteed, the deposition rate of the semiconductor layer 305 can be greatly increased, and the wrap plating problem can be greatly ameliorated. Although depositing the semiconductor layer 305 using the PEALD or PECVD processes cannot completely avoid the wrap plating of the semiconductor layer 305, the wrap plating range of the semiconductor layer 305 can be narrowed to a certain extent due to the limited region of plasma generation, thereby improving the production efficiency and yield to a certain extent, and reducing the technical bottleneck in a Low Pressure Chemical Vapor Deposition (LPCVD) technology such as frequent tube breakage caused by polysilicon deposition on a quartz tube wall. Therefore, the charge storage structure 1300 shown in FIG. 13 of the present application can have higher product quality, lower manufacturing cost, and higher production efficiency.

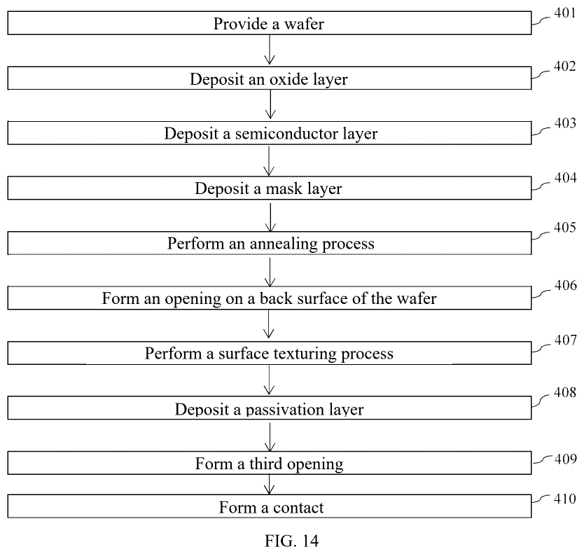

FIG. 14 is a flowchart of a method for manufacturing a charge storage structure according to an embodiment of the present application.

Referring to block 401, a wafer may be provided. A polishing process may be performed on the wafer. A cleaning process may be performed on the wafer. A cleaning after polishing process may be performed on the wafer.

Referring to block 402, an oxide layer may be deposited. The oxide layer may be deposited on a surface of the wafer. The oxide layer may be deposited on a front surface of the wafer. The oxide layer may be deposited on a back surface of the wafer, and the back surface is opposite to the front surface. The oxide layer may be deposited on a side surface of the wafer, and the side surface extends from the front surface to the back surface. The oxide layer may be deposited on the front surface, the back surface, and the side surface of the wafer. The oxide layer may be deposited on the back surface of the wafer. The oxide layer deposited on the back surface of the wafer may possibly be wrap plated to a portion of the side surface and a portion of the front surface, so that the front surface of the wafer may include an opening exposed from the oxide layer. This opening may be prepared for texturing the wafer later. The oxide layer may be deposited using the PECVD or the PEALD. The PEALD process may be performed at, for example, but not limited to, a temperature ranging from about 100° C. to 500° C. to form the oxide layer. The oxide layer may be, for example, but not limited to, a SiOx layer, with the thickness of less than 5 nanometers.

Referring to block 403, a semiconductor layer may be deposited. The semiconductor layer may be deposited on the oxide layer to cover the oxide layer, so as to prepare for subsequent formation of a back side field and connection to a contact. The semiconductor layer may be deposited using the PECVD or the PEALD. The PEALD process may be performed at, for example, but not limited to, a temperature ranging from about 100° C. to 500° C. to form the semiconductor layer. The semiconductor layer deposited on the oxide layer on the back surface of the wafer may possibly be wrap plated to a portion of the side surface and a portion of the front surface. The semiconductor layer may include a group IV element. The semiconductor layer may include a group V element. The semiconductor layer may include, for example, but not limited to, phosphorus. The semiconductor layer may include, for example, but not limited to, in-situ doped phosphorus. The semiconductor layer 305 may include, for example, but not limited to, phosphine (PH₃). The semiconductor layer may be any suitable type of semiconductor layer. The semiconductor layer 305 may be a silicon layer.

Referring to block 404, a mask layer may be deposited. The mask layer may be deposited on the semiconductor layer to cover the semiconductor layer. The mask layer may be deposited using the PECVD or the PEALD. The mask layer deposited on the semiconductor layer on the back surface of the wafer may possibly be wrap plated to a portion of the side surface and a portion of the front surface. The mask layer may be selected from, for example, but not limited to, aluminum oxide, silicon oxide, silicon nitride, silicon oxynitride, silicon carbide, or any combination thereof.

The opening on the front surface of the wafer may be exposed from the oxide layer, the semiconductor layer, and the mask layer.

In other embodiments, the oxide layer, the semiconductor layer, and the mask layer may be deposited on the back surface and the whole front surface of the wafer in sequence.

The oxide layer, the semiconductor layer and the mask layer can be deposited continuously in a process tube without breaking the vacuum by using a new tool which combines PEALD and PECVD two deposition techniques into one process tube.

Referring to block 405, an annealing process may be performed. An annealing process may be performed to adjust the crystal structure of the semiconductor layer (such as amorphous silicon or a mixture of amorphous silicon and polysilicon). The annealing process may be performed to activate PH₃ doping and to transform the silicon layer of the semiconductor layer 305 into a polysilicon layer. The phosphorus doped polysilicon layer may subsequently serve as a contact surface of the N+ region. In certain embodiments, the annealing process may be performed to achieve that the crystallinity of the semiconductor layer is greater than about 80%. In some other embodiments, the annealing process may be performed to achieve that the crystallinity of the semiconductor layer is between about 88% and about 90%.

Referring to block 406, an opening may be formed on the back surface of the wafer. A portion of the oxide layer, a portion of the semiconductor layer, and a portion of the mask layer on the back surface of the wafer may be removed to form the opening on the back surface of the wafer. A portion of the oxide layer, a portion of the semiconductor layer, and a portion of the mask layer may be removed using a laser process to form the opening on the back surface of the wafer. A portion of the oxide layer, a portion of the semiconductor layer, and a portion of the mask layer may be removed using any suitable process to form the opening on the back surface of the wafer. In some embodiments, preferably, a portion of the mask layer on the back surface of the wafer is removed to form the opening. This opening may be prepared for texturing the back surface of the wafer later.

Referring to block 407, an HF acid of chain/inline type wet-process equipment may be used to remove the mask layer on the front surface and the side surface, so that the semiconductor layer wrap plated on the side surface and the front surface is exposed.

Next, the semiconductor layer on the side surface and above the front surface of the wafer may be removed. A suitable chemical reagent may be used to remove the semiconductor layer. The semiconductor layer on the side surface and the front surface may be removed using cassette-type wet-process equipment through a chemical reagent, for example, but not limited to, HNO3, or KOH, or NaOH and an additive. Due to the protection of the mask layer, the semiconductor layer on the back surface of the wafer is not affected. Due to the automated connection between the chain/inline type wet-process equipment and the cassette-type wet-process equipment, the steps of removing the mask layer and removing the semiconductor layer may be efficiently and conveniently completed.

Next, the oxide layer on the side surface and above the front surface of the wafer may be removed. Any suitable process or suitable chemical reagent may be used to remove the oxide layer.

Next, a surface texturing process may be performed. The surface texturing process may be performed on wafer regions simultaneously exposed by the openings on both the front and back surfaces of the wafer. After the surface texturing process is performed, regions, which are not covered by the oxide layer and the semiconductor layer, on the front surface and the back surface of the wafer may form a pyramidal shape. In other embodiments, regions, which are not covered by the oxide layer and the semiconductor layer, on the front surface and the back surface of the wafer may form any one of an alkali polished shape, an acid polished shape, a micro-texture shape, or an inverted pyramidal shape. Performing the surface texturing process may repair damage caused by the laser process to the opening on the back surface of the wafer. A chemical solution (such as acid or alkali) may be used to perform the surface texturing process]. For example, in some embodiments, a pyramidal texture may be obtained by alkali treatment. For example, in other embodiments, a wormhole like texture may be obtained using acid treatment. Regardless of the type of the texture, the light trapping effect of the wafer (silicon wafer) can be enhanced. In other embodiments, the surface texturing process may be performed on the front surface of the wafer and the back surface of the wafer respectively, so that the front surface of the wafer and the back surface of the wafer may have different textured shapes. According to actual needs, the surface texturing process may be performed on the front surface of the wafer first, or the surface texturing process may be performed on the back surface of the wafer first.

Next, the remaining mask layer on the surfaces of the wafer may be removed. The mask layer located on the back surface of the wafer may be removed. The mask layer may be removed using the HF acid of the cassette-type wet-process equipment.

Orders of the removal of the mask, the removal of the oxide layer, and the removal of the semiconductor layer during the surface texturing may be flexibly adjusted according to actual needs.

Next, the surfaces of the wafer may be cleaned to provide high-quality and high-cleanliness samples for subsequent deposition.

Referring to block 408, a first passivation layer may be deposited. The first passivation layer may be deposited on the front surface and the back surface of the wafer. The first passivation layer may be deposited using ALD, CVD, or any suitable process. The first passivation layer that is deposited on two sides (namely, on the front surface and the back surface) may overcome the wrap plating problem caused by single-sided deposition. The formed first passivation layer may wrap the pyramidal part, the oxide layer, and the semiconductor layer on the front surface, the side surface, and the back surface of the wafer. The first passivation layer may be an AlOx layer. The first passivation layer may be, for example, but not limited to, Al₂O₃. The first passivation layer may be any suitable type of oxide layer. The first passivation layer may be a SiOx layer. The first passivation layer may be a stacked layer formed by the SiOx layer and the Al₂O₃. By use of the ALD deposition process to deposit the first passivation layer, the film uniformity and conformality of the deposition of the first passivation layer can be ensured, so that the charge storage structures of which various textures can be set have good quality.

Next, a second passivation layer may be deposited. The second passivation layer may be deposited on the first passivation layer to cover the first passivation layer. The second passivation layer may be deposited using ALD, CVD, PECVD, PEALD, or any suitable process to coat the first passivation layer. The second passivation layer may be, for example, but not limited to, a SiNx layer, a SiOx layer, a SiON layer, or any combined layer of the SiNx layer, the SiOx layer, and the SiON layer. The second passivation layer may be any suitable type of nitride layer. The second passivation layer may be an anti-reflection layer. The second passivation layer may provide further hydrogen passivation for the first passivation layer.

Next, referring to block 409, a portion of the first passivation layer and a portion of the second passivation layer on a portion, having a texture, on the back surface of the wafer are removed to form a third opening. The third opening exposes the wafer, which is convenient for forming a desired metal contact in the subsequent step and provides a high-quality interface for subsequent metal contacting. The laser process or any suitable process may be used to remove the passivation layers.

Referring to block 410, a contact may be formed.

The contact may be formed at the third opening on the back surface of the wafer. The contact may be set through a conventional screen printing process or any suitable process. The contact may be, for example, but not limited to, Al. The contact may be a base contact. In other embodiments of the present application, the contact may include any suitable material.

A co-firing process may be performed to form a first region at a portion that is adjacent to the contact and is in contact with the wafer. The first region may be connected to the contact. The first region may be a P+ region. The first region may be an N+ region. The first region does not include boron.

The co-firing process may be performed to allow another contact to pass through the second passivation layer and the first passivation layer to be connected to the semiconductor layer. Another contact may be Ag paste or silver aluminum paste. The Ag paste or silver aluminum paste is corrosive and may pass through the second passivation layer and the first passivation layer during the co-firing to be connected to the semiconductor layer. Therefore, it is not necessary to first open the second passivation layer and the first passivation layer to form an opening to connect the Ag paste or silver aluminum paste to the semiconductor layer. Another contact may be an emitter contact. In other embodiments of the present application, another contact may include any suitable material.

Next, an electric or light injection process may be performed to further improve the efficiency and stability of a solar cell.

The method shown in FIG. 14 of the present application may be used to manufacture a charge storage structure in a simpler and more efficient manner. In block 402 to block 404, the PEALD or PECVD process may be used to manufacture the oxide layer, the semiconductor layer, and the mask layer. The three layers may be sequentially completed in the same tube using the same equipment, which greatly reduces the manufacturing complexity, simplifies the process, and facilitates the technical mass production. In addition, the oxide layer and the semiconductor layer are deposited using the PEALD or PECVD process, instead of LPCVD, the thickness of the oxide layer can be well controlled, the uniformity, repeatability, and stability of the oxide layer with a mass production requirement can be guaranteed, and the deposition rate of the semiconductor layer can be greatly increased. Furthermore, the in-situ doping performed on the semiconductor layer does not affect the deposition rate, and can also reduce the technical bottleneck in the LPCVD technology such as frequent tube breakage caused by polysilicon deposition on the quartz tube wall. In addition, if the LPCVD process is used to deposit the oxide layer and the semiconductor layer, it is not possible to directly form the mask layer on the semiconductor layer, and the step of depositing the mask layer needs to be completed by changing the equipment. However, using the PEALD or PECVD process may directly form the mask layer on the semiconductor layer. Therefore, the method shown in FIG. 14 of the present application can be completed more efficiently at low cost with less equipment.

Secondly, in the method shown in FIG. 14 of the present application, after the mask layer is deposited, the annealing process may be performed to adjust the crystal structure of the semiconductor layer, without a high temperature of about 1000° C. to 1200° C. (that is required to perform boron diffusion related processes), which lowers the process difficulty, saves some production raw materials, and reduces the manufacturing cost. Meanwhile, due to a significant decrease in the maximum temperature that the wafer needs to withstand during the manufacturing of the entire charge storage structure, that is, since the wafer does not need to experience the high temperature of about 1000° C. to 1200° C., the warping of the wafer caused by the high temperature is reduced, the product yield of the charge storage structure is improved, and the energy consumption is reduced.

Furthermore, in the method shown in FIG. 14 of the present application, the double-sided texturing process (namely, texturing the front and back surfaces) is performed after the back side field is formed, which can provide higher-quality and high-cleanliness samples for subsequent coating, facilitate the subsequent deposition of another oxide layer and nitride layer, and improve the product quality and the production efficiency.

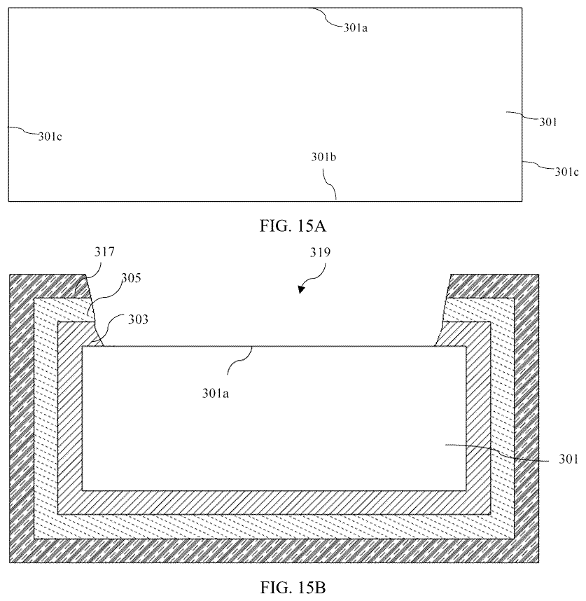

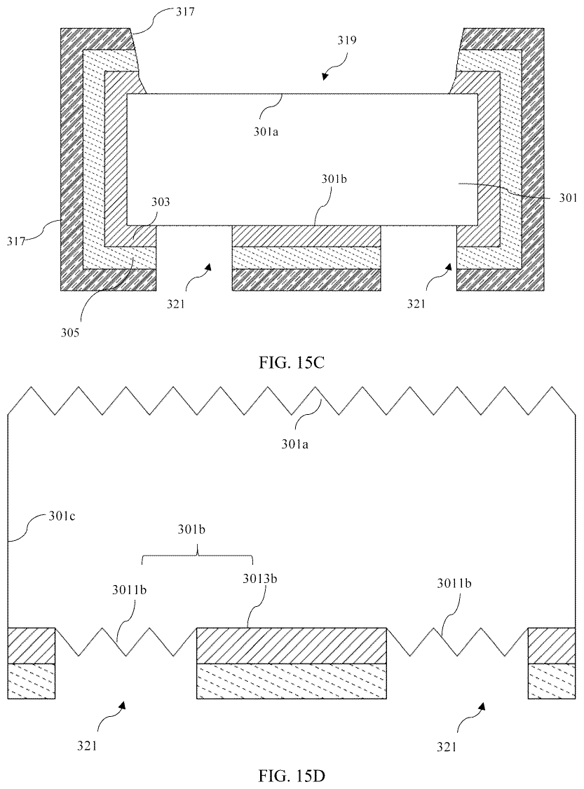

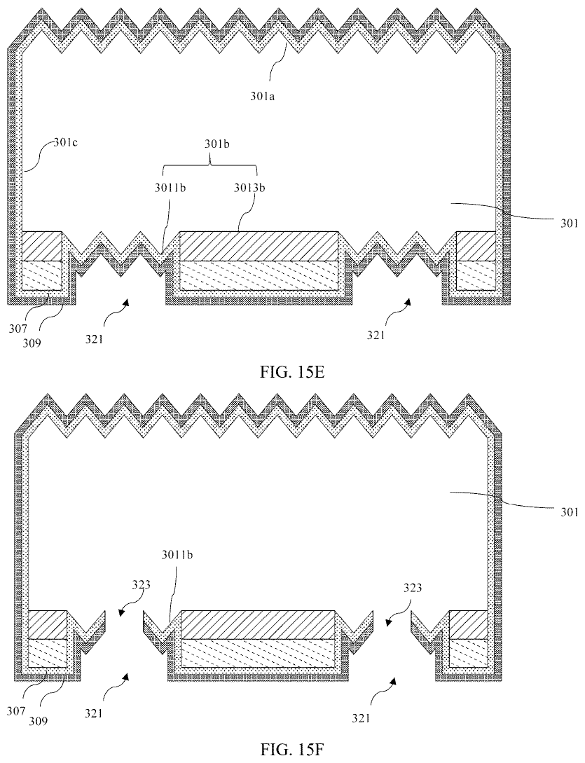

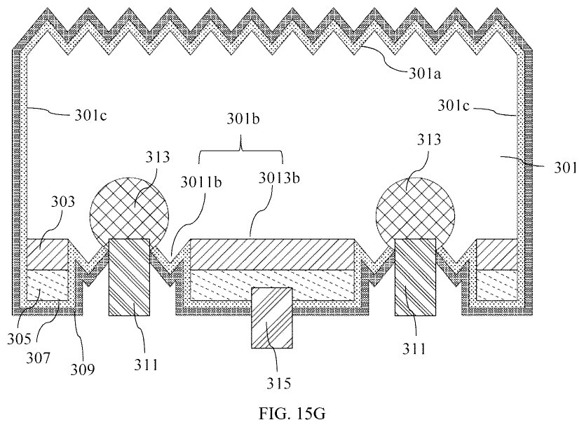

FIG. 15A, FIG. 15B, FIG. 15C, FIG. 15D, FIG. 15E, FIG. 15F, and FIG. 15G are schematic longitudinal cross section views of charge storage structures at different stages of the charge storage structure 1300, as shown in FIG. 13, manufactured by the method as shown in FIG. 14.

Referring to FIG. 15A, according to block 401, a wafer 301 may be provided. Conventional polishing and cleaning processes may be performed on the wafer 301. The wafer 301 has a front surface 301a, a back surface 301b opposite to the front surface 301a, and a side surface 301c located between the front surface 301a and the back surface 301b. The wafer 301 may be, for example, but not limited to, a P-type C—Si wafer. The wafer 301 may be any suitable type of wafer.

Referring to FIG. 15B, according to block 402, an oxide layer 303 may be deposited on the back surface 301b of the wafer 301. The oxide layer 303 may be deposited using PECVD or PEALD. The oxide layer 303 deposited on the back surface 301b of the wafer may possibly be wrap plated to a portion of the side surface 301c and a portion of the front surface 301a. The front surface 301a of the wafer 301 may include an opening 319 exposed from the oxide layer 303. The oxide layer 303 may be, for example, but not limited to, a SiOx layer with the thickness of less than about 5 nanometers.

According to block 403, the semiconductor layer 305 may be deposited on the oxide layer 303 on the back surface 301b to cover the oxide layer 303, so as to prepare for subsequent formation of a back side field and connection to a contact 315. The semiconductor layer 305 may be deposited using the PECVD or the PEALD. The semiconductor layer 305 deposited on the back surface 301b of the wafer may possibly be wrap plated to a portion of the side surface 301c and a portion of the front surface 301a. The semiconductor layer 305 may include a group IV element. The semiconductor layer 305 may include a group V element. The semiconductor layer 305 may include, for example, but not limited to, phosphorus. The semiconductor layer 305 may include, for example, but not limited to, in-situ doped phosphorus. The semiconductor layer 305 may be any suitable type of semiconductor material. The semiconductor layer 305 may include, for example, but not limited to, phosphine (PH₃).

According to block 404, the mask layer 317 may be deposited on the semiconductor layer 305 on the back surface 301b to cover the semiconductor layer 305. The mask layer 317 may be deposited using the PECVD or the PEALD. The mask layer 317 deposited on the back surface 301b of the wafer may possibly be wrap plated to a portion of the side surface 301c and a portion of the front surface 301a. The mask layer 317 may be selected from, for example, but not limited to, aluminum oxide, silicon oxide, silicon nitride, silicon oxynitride, silicon carbide, or any combination thereof.

The opening 319 on the front surface 301a of the wafer 301 may be exposed from the oxide layer 303, the semiconductor layer 305, and the mask layer 317.

According to block 405, after the mask layer 317 is deposited, an annealing process may be performed to adjust the crystal structure (such as polysilicon) of the semiconductor layer. In certain embodiments, the annealing process may be performed to achieve that the crystallinity of the semiconductor layer is greater than about 80%. In some other embodiments, the annealing process may be performed to achieve that the crystallinity of the semiconductor layer is between about 88% and about 95%. In certain embodiments, the annealing process may be performed to simultaneously activate PH₃ doping and to transform the semiconductor layer into a polysilicon layer.

Referring to FIG. 15C, according to block 406, a portion of the oxide layer 303, a portion of the semiconductor layer 305, and a portion of the mask layer 317 on the back surface 301b of the wafer 301 may be removed using a laser process to form an opening 321.

Referring to FIG. 15D, an HF acid of chain/inline type wet-process equipment may be used to remove the mask layer 317 on the front surface 301a and the side surface 301c of the wafer 301, so that the semiconductor layer 305 wrap plated on the front surface and the side surface is exposed.

The semiconductor layer 305 above the front surface 301a and on the side surface of the wafer 301 may be removed. A suitable chemical reagent may be used to remove the semiconductor layer 305. The semiconductor layer 305 on the front surface 301a and the side surface 301c may be removed using cassette-type equipment through a chemical reagent, for example, but not limited to, a KOH or NaOH and an additive. Next, the oxide layer 303 above the front surface 301a and on the side surface of the wafer 301 may be removed using a suitable chemical agent.

Next, a surface texturing process may be performed on a region formed by the opening 321 and the front surface 301a. After the surface texturing process is performed, the front surface 301a of the wafer 301 may form a pyramidal part, and the back surface 301b of the wafer 301 may form a pyramidal part 3011b. That is, the back surface 301b of the wafer 301 may include a pyramidal part 3011b and a flat part 3013b. In addition, damage caused by the laser process used in FIG. 15C to the back surface 301b may be repaired while forming the pyramidal shape required by the back surface 301b.

Next, the remaining mask layer on the surfaces of the wafer may be removed. The mask layer located on the back surface of the wafer may be removed. The mask layer may be removed using the HF acid of the cassette-type wet-process equipment.

Next, the surfaces of the wafer 301 may be cleaned to provide high-quality and high-cleanliness samples for subsequent deposition.

The removal of the redundant semiconductor layer 305, oxide layer 303, and mask layer 317 may also be completed through other suitable process steps.

Referring to FIG. 15E, according to block 408, a passivation layer 307 may be deposited on the front surface 301a and the back surface 301b. The passivation layer 307 may be deposited using ALD, CVD, or any suitable process. The passivation layer 307 that is deposited on two sides (namely, on the front surface 301a and the back surface 301b) may overcome the wrap plating problem caused by single-sided deposition. The passivation layer 307 may wrap the pyramidal part 3011b, the oxide layer 303, and the semiconductor layer 305 on the front surface 301a, the side surface 301c, and the back surface 301b of the wafer 301. The passivation layer 307 may be an AlOx layer. The passivation layer 307 may be, for example, but not limited to, Al₂O₃. The passivation layer 307 may be any suitable type of oxide layer. The passivation layer 307 may be a SiOx layer. The passivation layer 307 may be a stacked layer formed by the SiOx layer and the Al₂O₃.

A passivation layer 309 may be further deposited on the passivation layer 307 to cover the passivation layer 307. The passivation layer 309 may be deposited using ALD, CVD, PECVD, PEALD, or any suitable process to coat the passivation layer 307. The passivation layer 309 may be, for example, but not limited to, a SiNx layer, a SiOx layer, a SiON layer, or any combined layer of the SiNx layer, the SiOx layer, and the SiON layer. The passivation layer 309 may be any suitable type of nitride layer.

Referring to FIG. 15F, according to block 409, portions of the passivation layer 309 and the passivation layer 307 on the pyramidal part 3011b on the back surface 301b of the wafer 301 may be removed using the laser process to form an opening 323 for exposing the wafer 301. The portions of the passivation layer 309 and the passivation layer 307 may be removed using any suitable process.

Referring to FIG. 15G, a contact 311 may be formed in the opening 323. The contact 311 may be set using a conventional screen printing process or any suitable process. The contact 311 may be, for example, but not limited to, Al. The contact 311 may be a base contact. In other embodiments of the present application, the contact 311 may include any suitable material.

Next, a co-firing process may be performed to form a region 313 at a portion that is adjacent to the contact 311 and is in contact with the wafer 301. The region 313 may include a P+ region. The region 313 may be connected to the contact 311. In other embodiments of the present application, the contact 313 may include an N+ region.

Next, a contact 315 may be formed in a region outside the opening 323. The contact 315 may be set using a conventional screen printing process or any suitable process. The co-firing process may be performed to allow the contact 315 to pass through the passivation layer 309 and the passivation layer 307 to be connected to the semiconductor layer 305. The contact 315 may be Ag. The contact 315 may be an emitter contact. In other embodiments of the present application, the contact 315 may include any suitable material.

Finally, the charge storage structure 1300 as shown in FIG. 13 is obtained.

The method shown in FIG. 14 of the present application has fewer manufacturing steps, lower energy consumption, lower cost, and higher manufacturing efficiency compared to the prior art, and manufactured products have higher quality. Moreover, the charge storage structure of the present application can achieve different textures on the front and back surfaces of the wafer, taking into account the product requirements and the manufacturing cost.

The orders of the method for manufacturing the charge storage structure according to the embodiments of the present application are not limited to the steps and orders of the method shown in FIG. 14. Without departing from the teaching of the aforementioned spirit of the embodiments of the present application, suitable substitutions and modifications of the steps and/or orders of the method shown in FIG. 14 shall fall within the spirit of the embodiments of this patent application.

The technical contents and features of the present application have been disclosed above. However, those skilled in the art may still make various substitutions and modifications based on the teachings and disclosures of the present application that do not deviate from the spirit of the present application. Therefore, the protection scope of the present application should not be limited to the contents disclosed in the embodiments, but should include various substitutions and modifications that do not deviate from the present application, and be covered by the claims of this patent application.

1. A charge storage structure, comprising:
a wafer, having a first surface and a second surface opposite to the first surface, wherein the first surface has a first texture, and the second surface comprises a first part with a second texture and a second part connected to the first part;
a first polar region, configured to be in contact with the first part of the second surface; and
a second polar region, spaced apart from the first polar region and configured to be adjacent to the second part of the second surface;
wherein the first texture is different from the second texture.

2. The charge storage structure according to claim 1, wherein the first texture is any one of a pyramidal texture and an inverted pyramidal texture, and the second texture is any one of an alkali polished texture, an acid polished texture, a micro-texture, the pyramidal texture, and the inverted pyramidal texture.

3. The charge storage structure according to claim 1, further comprising an oxide layer covering the second part of the second surface of the wafer.

4. The charge storage structure according to claim 3, further comprising a semiconductor layer covering the oxide layer.

5. The charge storage structure according to claim 4, further comprising a first passivation layer, which covers the first surface, the first part of the second surface, a third surface of the wafer located between the first surface and the second surface, a side surface of the oxide layer, and a side surface of the semiconductor layer.

6. The charge storage structure according to claim 5, further comprising a second passivation layer covering the first passivation layer.

7. The charge storage structure according to claim 1, wherein the first polar region comprises a first metal contact and a region connected to the first metal contact.

8. (canceled)

9. The charge storage structure according to claim 6, wherein both the first passivation layer and the second passivation layer located on the first part of the second surface have a first opening, and the first metal contact of the first polar region passes through the first opening.

10. The charge storage structure according to claim 1, wherein the second polar region comprises a second metal contact connected to the semiconductor layer, and the second metal contact is connected to the semiconductor layer without passing through an opening.

11-21. (canceled)

22. A charge storage structure, comprising:
a wafer, having a first surface and a second surface opposite to the first surface, wherein the first surface has a first texture, and the second surface comprises a first part with a second texture and a second part connected to the first part;
a first polar region, configured to be in contact with the first part of the second surface; and
a second polar region, spaced apart from the first polar region and configured to be adjacent to the second part of the second surface;
wherein the first texture is any one of an alkali polished texture, an acid polished texture, a micro-texture, and an inverted pyramidal texture, and the second texture is any one of an alkali polished texture, an acid polished texture, a micro-texture, and an inverted pyramidal texture; and the first texture and the second texture are the same.

23. (canceled)

24. A method for manufacturing a charge storage structure, comprising:
depositing an oxide layer on a back surface of a wafer;
depositing a semiconductor layer on the oxide layer to cover the oxide layer;
depositing a mask layer on the semiconductor layer to cover the semiconductor layer; and
removing a portion of the mask layer on the back surface of the wafer to form a first opening.

25. The method for manufacturing the charge storage structure according to claim 24, wherein a front surface of the wafer opposite to the back surface comprises a second opening exposed from the mask layer, the semiconductor layer, and the oxide layer.

26. The method for manufacturing the charge storage structure according to claim 25, further comprising: performing a surface texturing process on a region where the first opening and the front surface of the wafer are located.

27. The method for manufacturing the charge storage structure according to claim 24, further comprising: depositing the oxide layer on a side surface of the wafer located between the front surface and the back surface.

28. The method for manufacturing the charge storage structure according to claim 26, further comprising: removing the mask layer and the semiconductor layer which are located on the front surface and the side surface of the wafer before performing the surface texturing process.

29. The method for manufacturing the charge storage structure according to claim 26, further comprising: removing the oxide layer located on the front surface and the side surface of the wafer and the mask layer on the back surface of the wafer.

30. The method for manufacturing the charge storage structure according to claim 29, further comprising:
depositing a first passivation layer on the front surface and the back surface;
depositing a second passivation layer on the first passivation layer to cover the first passivation layer; and
removing a portion of the first passivation layer and a portion of the second passivation layer on the back surface of the wafer from the first opening to form a third opening that exposes the wafer.

31. The method for manufacturing the charge storage structure according to claim 30, further comprising:
forming a first contact in the third opening; and
performing a co-firing process to form a first region at a portion that is adjacent to the first contact and is in contact with the wafer.

32. The method for manufacturing the charge storage structure according to claim 31, further comprising:
forming a second contact in a region outside the third opening; and
performing the co-firing process to allow the second contact to pass through the second passivation layer and the first passivation layer to be connected to the semiconductor layer.

33. The method for manufacturing the charge storage structure according to claim 24, wherein the oxide layer is deposited using a Plasma Enhanced Chemical Vapor Deposition (PECVD) or Plasma Enhanced Atomic Layer Deposition (PEALD).

34. The method for manufacturing the charge storage structure according to claim 24, wherein the semiconductor layer is deposited using PECVD or PEALD.

35. The method for manufacturing the charge storage structure according to claim 24, wherein the mask layer is deposited using PECVD or PEALD.

36-38. (canceled)

39. The method for manufacturing the charge storage structure according to claim 24, wherein the mask layer is selected from aluminum oxide, silicon oxide, silicon nitride, silicon oxynitride, silicon carbide, or any combination thereof.

40. The method for manufacturing the charge storage structure according to claim 24, further comprising performing an annealing process after depositing the mask layer.

41-44. (canceled)

45. The charge storage structure according to claim 2, wherein the micro-texture is a surface with both an alkali polished shape and a pyramidal shape.

46. The charge storage structure according to claim 22, wherein the micro-texture is a surface with both an alkali polished shape and a pyramidal shape.

47. The method for manufacturing the charge storage structure according to claim 24, wherein the oxide layer, the semiconductor layer and the mask layer are done in a single process by the same tube of one equipment.
